(19) United States
(12) Patent Application Publication
(10) Pub. No.: US 2018/0268878 A1
(43) Pub. Date: Sep. 20, 2018

(54) NON-VOLATILE SEMICONDUCTOR MEMORY DEVICE

(71) Applicant: TOSHIBA MEMORY CORPORATION, Tokyo (JP)

(72) Inventors: Ryu OGIWARA, Yokohama Kanagawa (JP); Daisaburo TAKASHIMA, Yokohama Kanagawa (JP)

(21) Appl. No.: 15/909,448

(22) Filed: Mar. 1, 2018

(30) Foreign Application Priority Data
Mar. 16, 2017 (JP) 2017-051293

(51) Int. Cl. G11C 7/06; G11C 5/14

(52) U.S. Cl. CPC G11C 7/062; G11C 13/0004; G11C 5/14

(57) ABSTRACT

A variable resistance non-volatile semiconductor memory device comprises a memory cell having variable resistance element connected in series with a selection transistor. The selection transistor has a control terminal connected to a word line. A first end of the memory cell is connected to a bit line. A second end of the memory cell is connected to a first power supply line. An additional resistor is connected between a second power supply line and the bit line. The first power supply line is a low potential and the second power supply line is a high potential. During a reading operation of the memory cell, a read current flows through the first resistor and the memory cell.

### CROSS-REFERENCE TO RELATED APPLICATION

This application is based upon and claims the benefit of priority from Japanese Patent Application No. 2017-051293, filed Mar. 16, 2017, the entire contents of which are incorporated herein by reference.

### FIELD

Embodiments described herein relate generally to a non-volatile semiconductor memory device.

### BACKGROUND

A resistive random access memory (ReRAM), a phase-change random access memory (PCMRAM), an interfacial phase-change random access memory (iPCM), a conduction bridge random access memory (CBRAM), a magnetoresistive random access memory (MRAM), and the like, each include a variable resistance element in a memory cell. These memory types are being developed for various applications in next generation non-volatile semiconductor memory devices.

### DESCRIPTION OF THE DRAWINGS

FIG. 1 is a block diagram illustrating a non-volatile semiconductor memory device of a first embodiment.

FIG. 2 is a circuit diagram schematically illustrating a main part of the circuit linked to one bit line in the first embodiment.

FIG. 3A and FIG. 3B are circuit diagrams illustrating memory cells in a modification example of the first embodiment.

FIG. 3C is a variation of the embodiment illustrated in FIGS. 3A-B.

FIG. 4 is an I-V curve illustrating operating points of a multilevel cell in a method for reading data in the memory cell in a first comparison example (a constant voltage method), a second comparison example (constant current method), and a third comparison example (e-M-metric).

FIG. 5 is a circuit diagram schematically illustrating a main part of a variable resistance non-volatile semiconductor memory device in the first comparison example (the constant voltage method).

FIG. 6 is a circuit diagram schematically illustrating a main part of a variable resistance non-volatile semiconductor memory device in the second comparison example (the constant current method).

FIG. 7 is a circuit diagram schematically illustrating a main part of a variable resistance non-volatile semiconductor memory device in the third comparison example (e-M-metric).

FIG. 8 is a diagram schematically illustrating changes of a bit line potential of the embodiments and comparison examples.

FIG. 9A and FIG. 9B are diagrams for comparing read times of the memory cell in the first embodiment and in the comparison examples.

FIG. 10A and FIG. 10B are diagrams for comparing a read current consumptions of the memory cell in the first embodiment and in the comparison examples.

FIG. 11 is a circuit diagram schematically illustrating a main part of the circuit linked to one bit line in a second embodiment.

FIG. 12 is a diagram illustrating a relationship between a pull-up voltage, a set voltage, and reset voltage in a second embodiment.

FIG. 13A and FIG. 13B are diagrams for comparing read times of the memory cells in the second embodiment and in the comparison examples.

FIG. 14A and FIG. 14B are diagrams for comparing the read current consumption of the memory cell in the second embodiment and in the comparison examples.

FIG. 15 is a circuit diagram schematically illustrating a main part of a circuit linked to a pair of bit lines in a third embodiment.

FIG. 16 is a timing chart illustrating a read operation of the memory cell in a low resistance state in the third embodiment.

FIG. 17 is a timing chart illustrating a read operation of the memory cell in a high resistance state in the third embodiment.

### DETAILED DESCRIPTION

An example embodiment provides a variable resistance non-volatile semiconductor memory device capable of both minimizing a read time and reducing a read current consumption.

In general, according to one embodiment, a variable resistance non-volatile semiconductor memory device comprises a memory cell having a variable resistance element connected in series with a selection transistor. The selection transistor has a control terminal connected to a word line. A first end of the memory cell is connected to a bit line. A second end of the memory cell is connected to a first power supply line. A first resistor, also referred to as an additional resistor, is connected between a second power supply line and the bit line. Here, the first power supply line is a low potential (e.g., ground potential) and the second power supply line is a high potential (e.g., Vdd). During a reading operation of the memory cell, a read current flows through the first resistor and the memory cell.

Hereinafter, example embodiments of the present disclosure will be described with reference to the drawings.

### First Embodiment

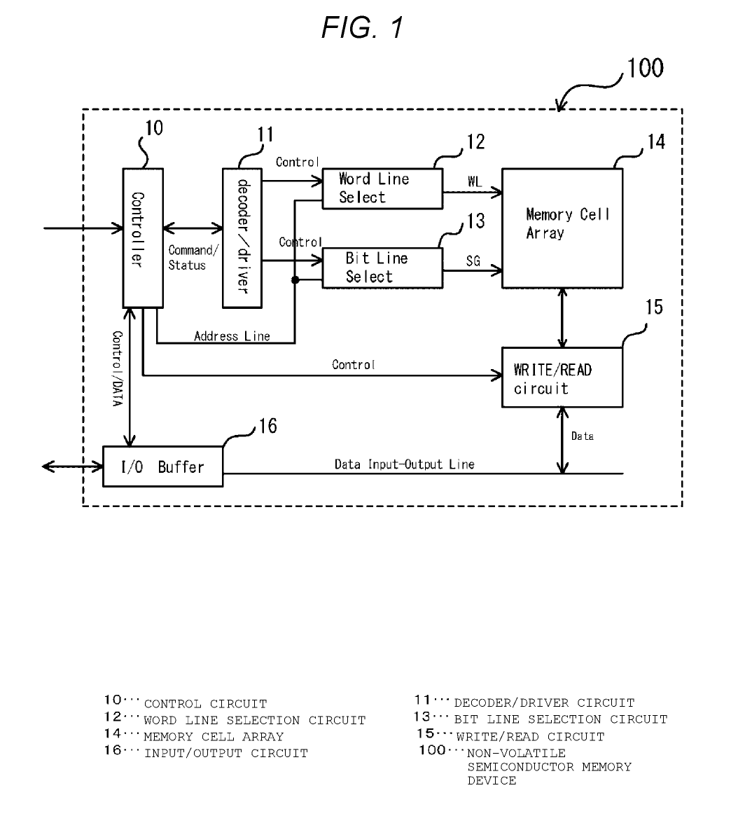

First, a non-volatile semiconductor memory device of a first embodiment will be described with reference to the drawings. FIG. 1 is a block diagram illustrating a non-volatile semiconductor memory device of a first embodiment. In the first embodiment, an additional resistor is provided between a constant voltage power supply for reading and a bit line and the additional resistor and the memory cell are connected to each other via the bit line, and thus, both minimizing the read time of the memory cell and reducing the read current consumption can be achieved.

As illustrated in FIG. 1, a non-volatile semiconductor memory device 100 includes a control circuit 10, a decoder/driver circuit 11, a word line selection circuit 12, a bit line selection circuit 13, a memory cell array 14, a write/read circuit 15, and an input/output circuit 16. The write/read circuit 15 may also be referred to as a sense amplifier circuit 15. The non-volatile semiconductor memory device 100 is a phase change random access memory (PCRAM).

The control circuit 10 performs overall control of the non-volatile semiconductor memory device 100. When receiving a write/read request, the control circuit 10 issues a command to the circuits in the non-volatile semiconductor memory device 100. The control circuit 10 exchanges commands/status with the decoder/driver circuit 11. The control circuit 10 transmits address information to the word line selection circuit 12 via an address line. The control circuit 10 transmits address information to the bit line selection circuit 13 via an address line. The control circuit 10 transmits control signals for writing, pre-charging, reading, and the like to the write/read circuit 15. The control circuit 10 transmits control signals to the input/output circuit 16 and exchanges the data with the input/output circuit 16.

The decoder/driver circuit 11 transmits the control signal to the word line selection circuit 12. The decoder/driver circuit 11 transmits the control signal to the bit line selection circuit 13. The word line selection circuit 12 selects a word line based on the control signal from the decoder/driver circuit 11 and the address information from the control circuit 10. The bit line selection circuit 13 selects a bit line based on the control signal from the decoder/driver circuit 11 and the address information from the control circuit 10.

In the memory cell array 14, a plurality of memory cells, a plurality of word lines, and a plurality of bit lines are arrayed. The write/read circuit 15 performs writing, pre-charging, and reading to and from the memory cell based on the control signal from the control circuit 10. The input/output circuit 16 exchanges the data with the write/read circuit 15. The input/output circuit 16 exchanges the data with the outside based on the command from the control circuit.

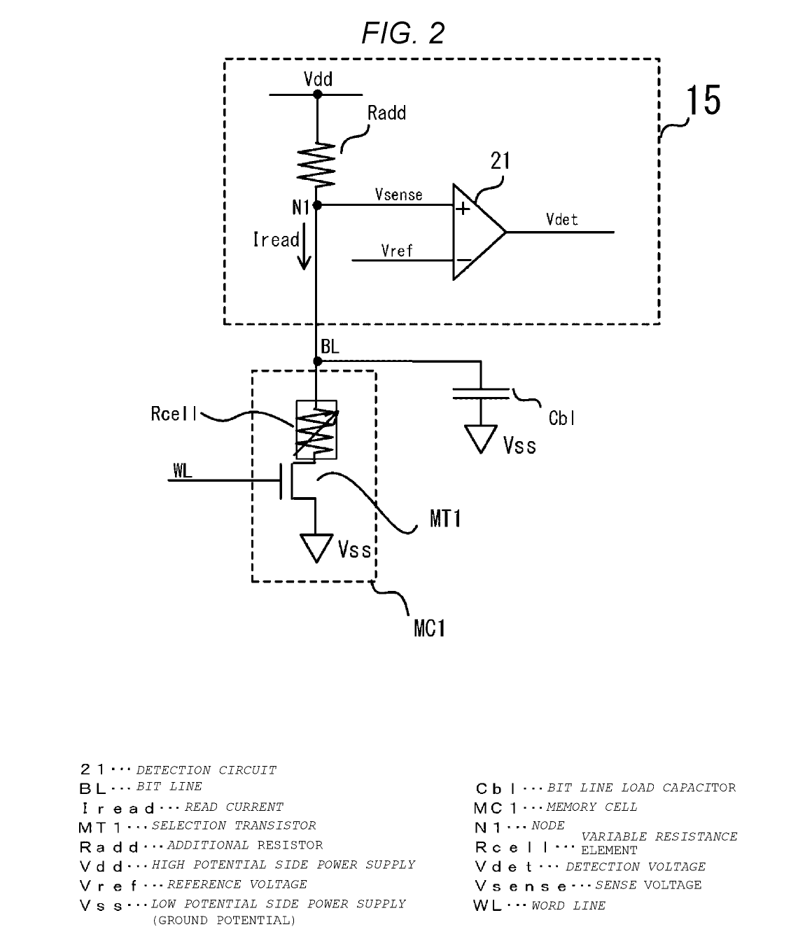

As illustrated in FIG. 2, the write/read circuit 15 includes an additional resistor Radd and a detection circuit 21. One end of the additional resistor Radd is connected to the high potential side power supply Vdd, and the other end is connected to the node N1. The write/read circuit 15 is connected to the memory cell MC1 via a bit line BL. The detection circuit 21 compares and amplifies a sense voltage Vsense and a reference voltage Vref, and outputs a detection voltage Vdet. The selection transistor MT1 of the memory cell MC1 enters an ON state at the time of the read operation and the write operation.

A bit line load capacitor Cbl is formed between the bit line BL and a low potential side power supply (e.g., ground potential) Vss.

The memory cell MC1 includes the selection transistor MT1 and a variable resistance element Rcell. One end (drain) of the selection transistor MT1 is connected to the variable resistance element Rcell, the other end (source) is connected to the low potential side power supply Vss, and a control terminal (gate) is connected to the word line WL. One end of the variable resistance element Rcell is connected to the bit line BL and the other end is connected to the one end (drain) of the selection transistor MT1, and the resistance value changes according to the phase change of a film and then, the different resistance values are stored as multilevel data.

A non-inverting amplifier terminal (+) on the input side of the detection circuit 21 is connected to the node N1, and the reference voltage Vref is input to an inverting amplifier terminal (−) on the input side thereof. The detection circuit 21 compares the voltage at the inverting amplifier terminal (−) on the input side thereof and the voltage at the non-inverting amplifier terminal (+) on the input side thereof with the voltage at the inverting amplifier terminal (−) on the input side as a reference.

During the reading of the data stored in the memory cell MC1, a constant voltage is applied to one end of the additional resistor Radd from the high potential side power supply Vdd, and a read current Iread flows through the resistance Radd and the memory cell MC1. When the read current Iread flows through the Node N1 (at the other end of the additional resistor Radd), the voltage at the node N1 becomes the sense voltage Vsense.

The sense voltage Vsense is input to the non-inverting amplifier terminal (+) on the input side of the detection circuit 21 and the reference voltage Vref is input to the inverting amplifier terminal (−) on the input side thereof, and the detection circuit 21 performs a comparison and outputs the result of comparison as the detection voltage Vdet. In a case where any of the multilevel data is stored in the variable resistance element Rcell, the detection voltages Vdet are output a multiple number of times while changing the value of the reference voltage Vref to narrow down the value of the stored data in the variable resistance element Rcell.

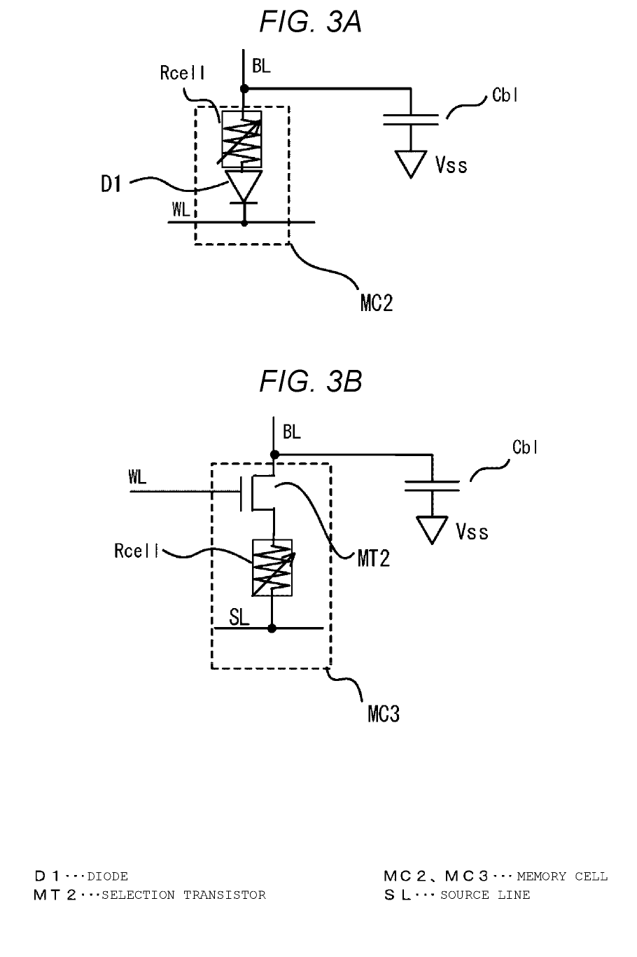

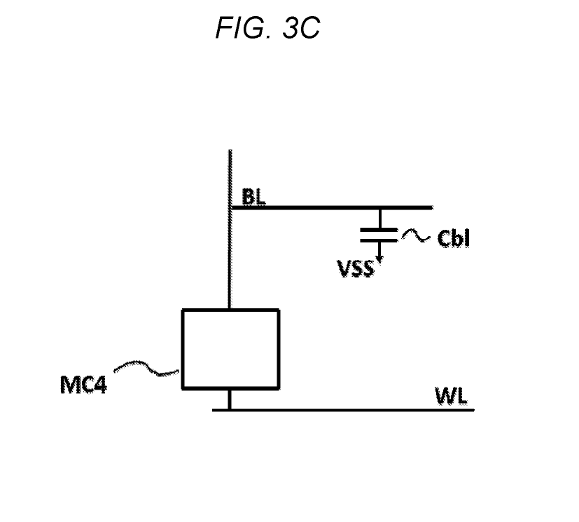

In the present embodiment, a memory cell configured with the variable resistance element Rcell is used as the memory cell MC1. However, a memory cell MC2 illustrated in FIG. 3A or a memory cell MC3 illustrated in FIG. 3B or a memory cell MC4 illustrated in FIG. 3C may be used.

As illustrated in FIG. 3A, the memory cell MC2 includes a variable resistance element Rcell and a diode D1. One end of the variable resistance element Rcell is connected to the bit line BL. An anode of the diode D1 is connected to the other end of the variable resistance element Rcell and a cathode of the diode D1 is connected to the word line WL. Here, the diode D1 is used as a type of switching element.

As illustrated in FIG. 3B, the memory cell MC3 includes a selection transistor MT2 and a variable resistance element Rcell. One end (drain) of the selection transistor MT2 is connected to the bit line BL, and a control terminal (gate) is connected to the word line WL. One end of the variable resistance element Rcell is connected to the other end (source) of the selection transistor MT2, and the other end thereof is connected to the low potential side power supply. Here, the diode D1 is used as a type of switching element.

In FIG. 3C, memory cell MC4 has the switching function. One end of the memory cell MC4 is connected to the bit line BL, and the other end of the memory cell MC4 is connected to the word line WL. By applying the predetermined current/voltage (writing current/voltage) to the memory cell MC4 through the bit line BL, the resistance state of the memory cell MC4 is controlled. Upon ending this current/voltage application (writing current/voltage), the resistance state (state A) of the memory cell MC4 is maintained.

By applying the predetermined current/voltage (reading current/voltage), which is lower than the predetermined current/voltage (writing current/voltage) to the memory cell MC4, the low resistance state or the high resistance state can be detected (read operation) without changing the above-mentioned resistance state (state A) of the memory cell MC4. Because the memory cell MC4 has the current voltage characteristic of a nonlinear element, the current flows minimally when the low voltage (“Low V”) is applied and the current flows when the predetermined voltage, which is higher than (or larger than, or more than) “Low V”, is applied. Accordingly, the memory cell MC4 has the switching function and non-volatile characteristics.

In the present embodiment, a method is adopted, in which the constant voltage is applied and a voltage value determined by a resistance division using the variable resistance element Rcell and the additional resistor Radd. Details thereof will be described later.

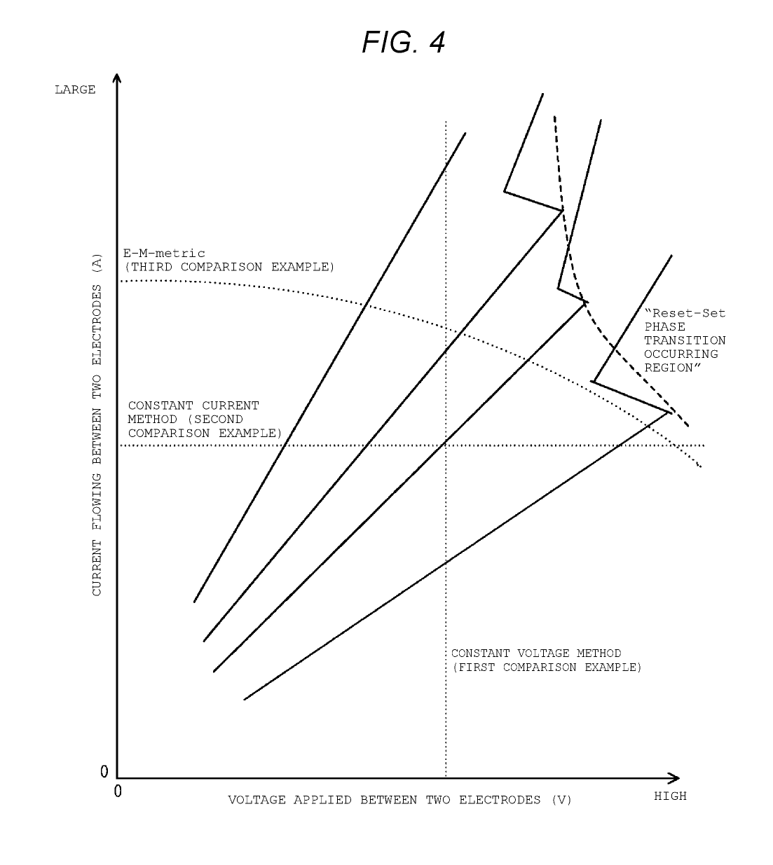

Next, a method for reading data in the memory cell in comparison examples of the related art will be described with reference to FIG. 4. FIG. 4 is an I-V curve illustrating operating points of a multilevel cell in methods for reading data in the memory cell for multiple comparison examples {a first comparison example (a constant voltage method), a second comparison example (constant current method), and a third comparison example (e-M-metric)}.

In the first comparison example (the constant voltage method), a constant voltage is input and a current flowing between both electrodes is measured. In the second comparison example (the constant current method), a constant current is caused to flow and a voltage between both electrodes are measured. In the third comparison example (e-M-metric), the additional resistor Radd and the variable resistance element Rcell are arranged in parallel and a constant voltage is applied, and then, a current flowing between both electrodes is measured. Additional details will be described later.

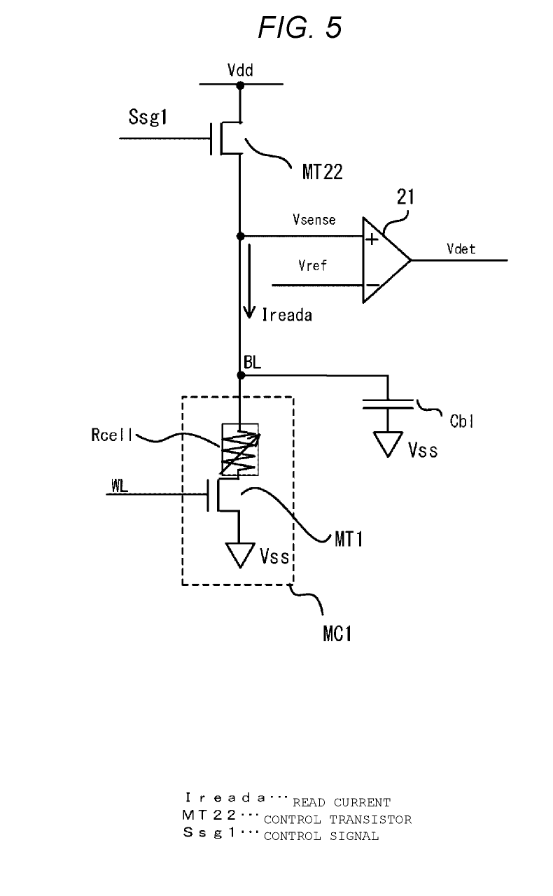

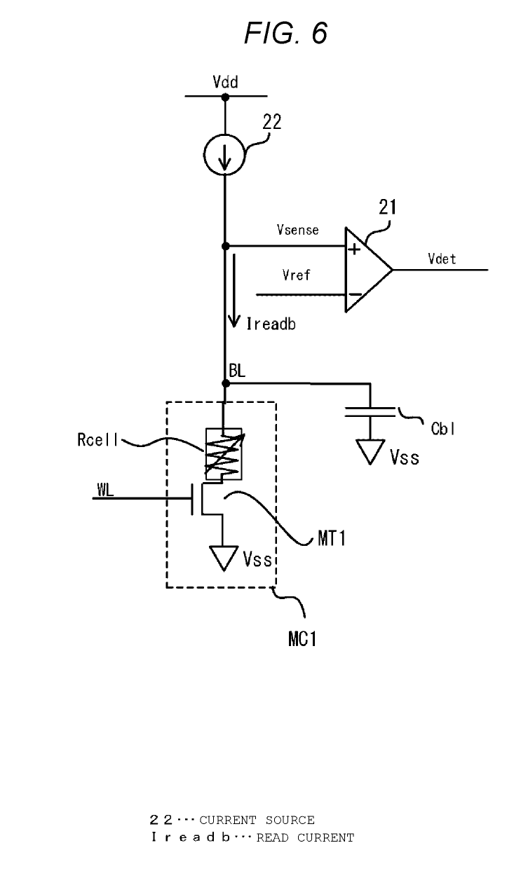

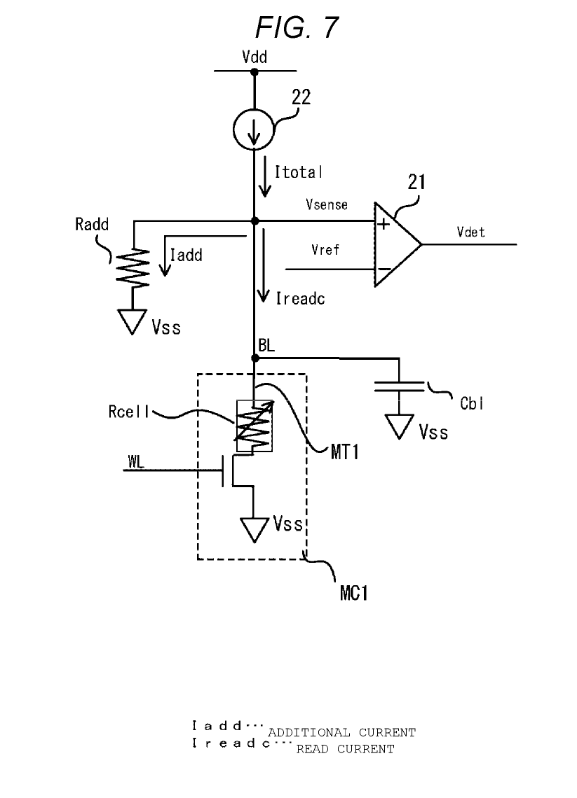

A read circuit part of a variable resistance non-volatile semiconductor memory device in the first to third comparison examples will be described with reference to FIG. 5 to FIG. 7. FIG. 5 is a circuit diagram schematically illustrating the main part of the variable resistance non-volatile semiconductor memory device in the first comparison example (the constant voltage method). FIG. 6 is a circuit diagram schematically illustrating the main part of the variable resistance non-volatile semiconductor memory device in the second comparison example (the constant current method). FIG. 7 is a circuit diagram schematically illustrating the main part of the variable resistance non-volatile semiconductor memory device in the third comparison example (e-M-metric). Portions different from the first embodiment will be described.

As illustrated in FIG. 5, in the first comparison example, a control transistor MT22 is provided, one end (drain) of which is connected to the high potential side power supply Vdd, a control signal Ssg1 is input to a control terminal (gate), and the other end (source) of which is connected to the bit line BL. The control transistor MT22 enters an ON state when the control signal Ssg1 (in an enable state) is input to the control terminal (gate). The control transistor MT22 then supplies a read voltage to the bit line BL.

As illustrated in FIG. 6, in the second comparison example, a current source 22 is provided, one end of which is connected to the high potential side power supply Vdd and the other end of which is connected to the bit line BL. When a constant voltage is supplied, the current source 22 supplies a constant read current Ireadb to the bit line BL.

As illustrated in FIG. 7, in the third comparison example, a current source 22 is provided, one end of which is connected to the high potential side power supply Vdd and the other end of which is connected to the bit line BL. An additional resistor Radd is provided, one end of which is connected to the high potential side power supply Vdd and the other end of which is connected to the low potential side power supply Vss. When a constant voltage is supplied, the current source 22 causes an additional current Iadd to flow through the additional resistor Radd and causes the read current Ireadc to flow through the bit line BL.

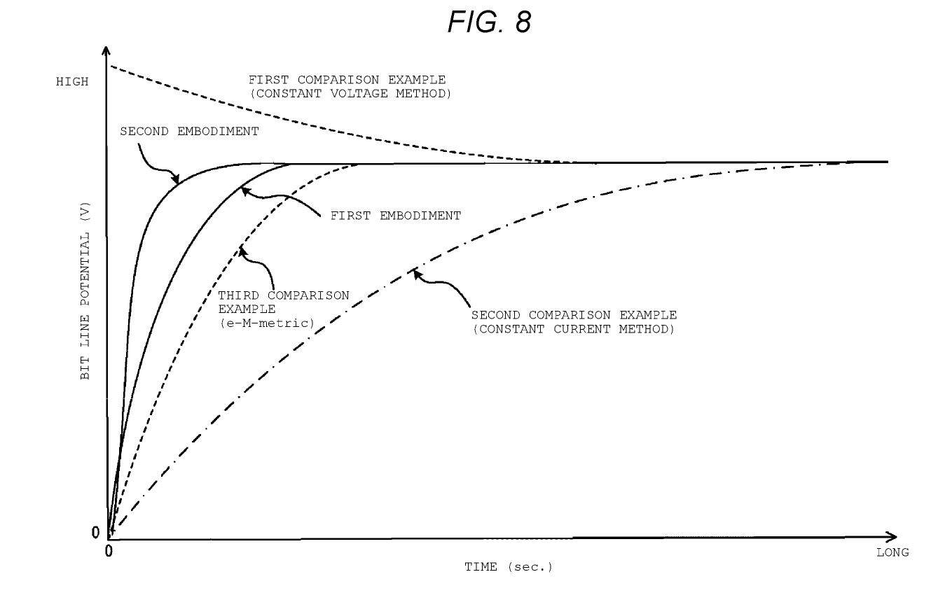

Next, a change of the bit line potential will be described with reference to FIG. 8. FIG. 8 is a diagram schematically illustrating changes of a bit line potential in the first and second embodiments and the comparison examples

As illustrated in FIG. 8, in the first embodiment, a time to reach a certain bit line potential is short as compared to that in the third comparison example (e-M-metric). In the second comparison example (the constant current method), the time to reach the certain bit line potential is extremely long as compared to that of the first embodiment and the third comparison example (e-M-metric). In the first comparison example, the bit line potential gradually decreases and the time to reach the certain bit line potential is still long as compared to that of the first embodiment and the third comparison example (e-M-metric).

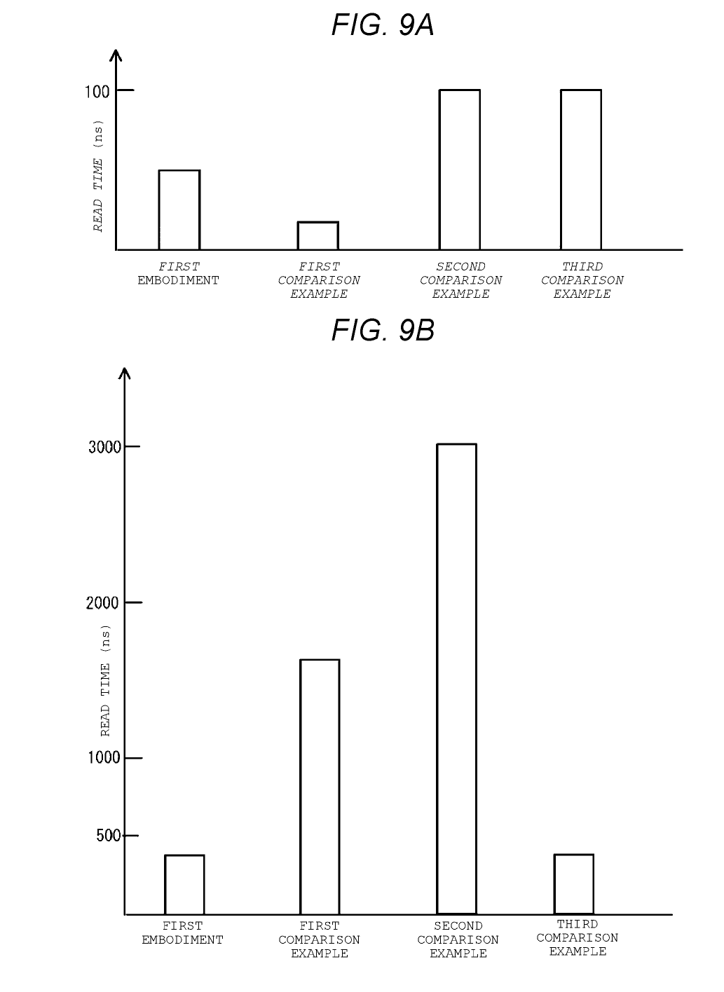

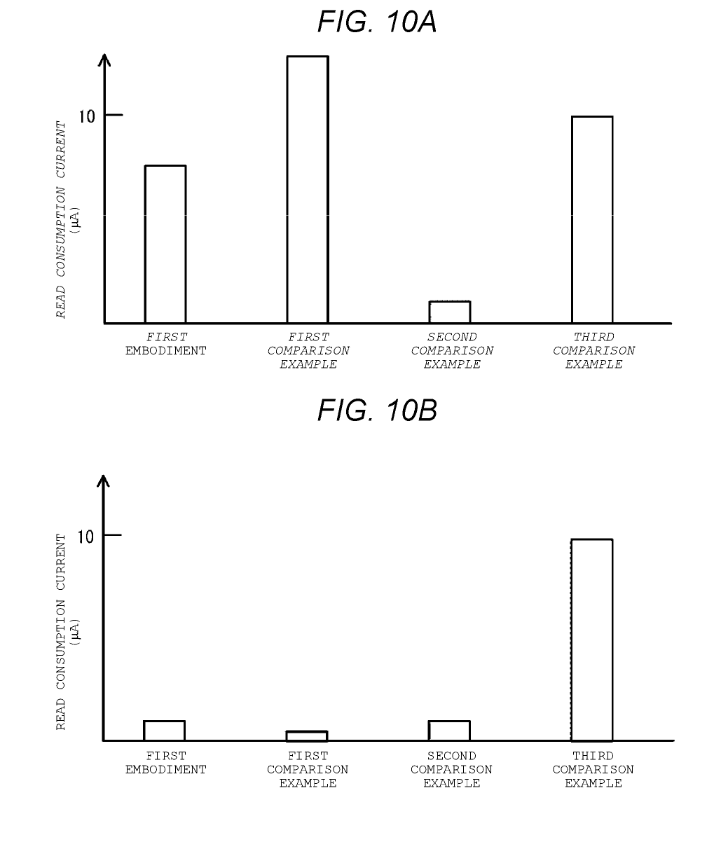

Next, a read time of the memory cell and a read current consumption of the memory cell will be described with reference to FIGS. 9A, 9B and FIGS. 10A, 10B. FIG. 9A and FIG. 9B are diagrams for comparing read times of the memory cell in the first embodiment (example embodiment) and in the comparison examples. FIG. 10A and FIG. 10B are diagrams for comparing a read current consumptions of the memory cell in the first embodiment and in the comparison examples. FIG. 9A and FIG. 10A indicate characteristics for the lowest resistance value cell in the multilevel data, and FIG. 9B and FIG. 10B indicate characteristics for the highest resistance value cell in the multilevel data. Here, the read current consumption means the current consumed in the read operation.

As illustrated in FIG. 9A, the read time in the lowest resistance value cell in the first embodiment can be shortened to one-half compared to that in the second and third comparison examples. The read time in the lowest resistance value cell in the first embodiment is 2.5 times longer than that of the first comparison example.

As illustrated in FIG. 9B, the read time in the highest resistance value cell in the first embodiment can be shortened to one-fifth compared to that in the first comparison example, and can be shortened to one-tenth compared to that in the second comparison example. The read time in the highest resistance value cell in the first embodiment is the same value as that in the third comparison example.

As illustrated in FIG. 10A, the read current consumption of the lowest resistance value cell in the first embodiment is reduced to approximately one-half compared to that in the first comparison example, and is reduced to four-fifths compared to that in the third comparison example. The read current consumption of the lowest resistance value cell in the first embodiment is approximately eight times larger compared to that in the second comparison example.

As illustrated in FIG. 10B, the read current consumption of the highest resistance value cell in the first embodiment is reduced to one-tenth compared to that in the third comparison example. The read current consumption of the highest resistance value cell in the first embodiment has the same value as that in the second comparison example, and is ten times larger than that in the first comparison example.

As described above, the additional resistor Radd and the write/read circuit 15 are provided in the non-volatile semiconductor memory device in the first embodiment. During an operation for reading the data stored in the memory cell MC1, a constant voltage is applied to one end of the additional resistor Radd from the high potential side power supply Vdd, and a read current Iread flows through the additional resistor Radd and the memory cell MC1. When the read current Iread flows through the Node N1, the voltage at the node N1 is the sense voltage Vsense. The sense voltage Vsense is input to the non-inverting amplifier terminal (+) on the input side of the detection circuit 21 and the reference voltage Vref is input to the inverting amplifier terminal (−) on the input side thereof, and then, the detection circuit 21 performs the comparison and outputs the result of comparison as the detection voltage Vdet.

The constant voltage is divided by two resistors in series, that is, the additional resistor Radd and the variable resistance element Rcell, and thus, the bit line potential V(BL) can be determined at a high speed, minimizing the read time of the memory cell.

Furthermore, as seen from the high potential side power supply Vdd, the additional resistor Radd and the variable resistance element Rcell are connected to each other in series, not parallel, therefore, a reduction in the read current consumption can be achieved. In this way, both the minimization of the read time of the memory cell and the reduction of the read current consumption can be achieved.

In the first embodiment, the non-volatile semiconductor memory device is described as PCRAM, but is not necessarily limited thereto. For example, the present embodiment can also be applied to memories that store data using resistance change elements such as a ReRAM, an iPCM, a CBRAM, MRAM, or the like.

### Second Embodiment

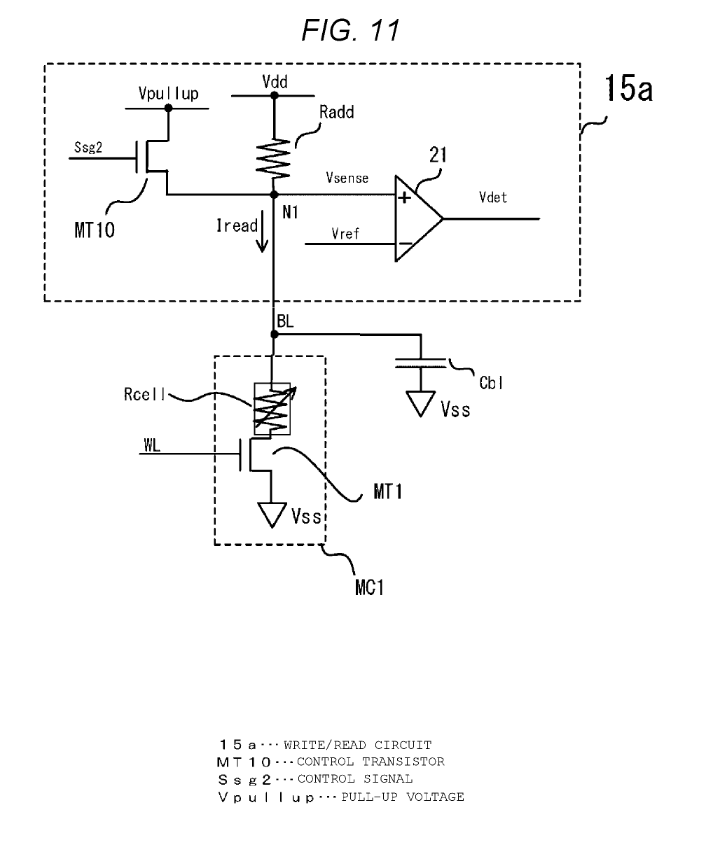

Next, a non-volatile semiconductor memory device of a second embodiment will be described with reference to the drawings. FIG. 11 is a diagram illustrating a write/read circuit in the present embodiment. In the present embodiment, an additional resistor is provided between the constant voltage power supply and the bit line, the additional resistor and the memory cell are connected to each other in series via the bit line, a pull-up voltage is applied between the additional resistor and the bit line, and thus, both the minimization of the read time of the memory cell and reduction of the read current consumption can be achieved.

Hereinafter, the same reference signs will be given to the same configuration elements as those of the first embodiment, and the description thereof will be omitted, and only different portions will be described.

As illustrated in FIG. 11, a write/read circuit 15a of a non-volatile semiconductor memory device includes an additional resistor Radd, a detection circuit 21, and a control transistor MT10. The write/read circuit 15a is connected to the memory cell MC1 via the bit line BL. The non-volatile semiconductor memory device in the present embodiment is a PCRAM, which is a phase-change memory.

A pull-up voltage Vpullup is applied to one end (drain) of the control transistor MT10 and the other end (source) is connected to the node N1, and a control signal Ssg2 is input to a control terminal (gate). Before the read operation of the memory cell MC1, the control signal Ssg2 is in an enable state (for example, “high” level) and the control transistor MT10 enters an ON state and the node N1 may be precharged to the pull-up voltage Vpullup.

At the time of the read operation of the memory cell MC1, the control signal Ssg1 is in a disable state (for example, “low” level), and then, the control transistor MT10 enters an OFF state, and thus, the pre-charge is cut off. It is possible to reduce the read time of the memory cell MC1 by precharging the node N1 to the pull-up voltage Vpullup.

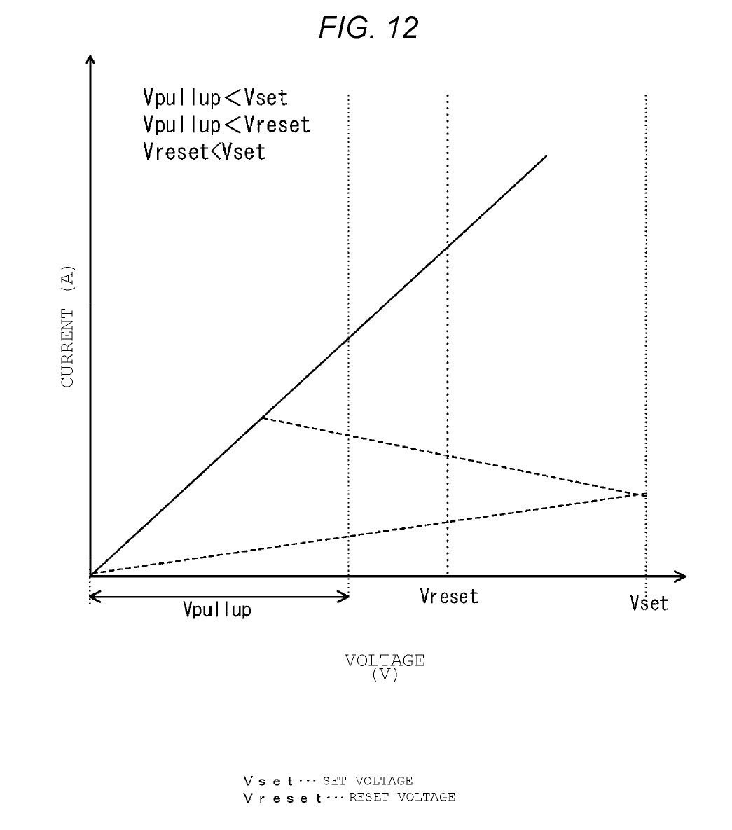

=A set value of the pull-up voltage Vpullup is described with reference to FIG. 12. FIG. 12 is a diagram illustrating a relationship between the pull-up voltage and a set voltage.

As illustrated in FIG. 12, the relationships between the pull-up voltage Vpullup, the set voltage Vset, the reset voltage Vreset is set according to the following relations: Vpullup<Vset and Vpullup<Vreset. The set voltage Vset is a voltage that causes a phase change of a film in the variable resistance element Rcell and causes a phase transition from a high resistance reset state to a low resistance set state. In addition, the reset voltage Vreset is a voltage that causes a phase change of the film in the variable resistance element Rcell and causes a phase transition from the low resistance set state to the high resistance reset state.

In addition, though the reset voltage Vreset is set according to the following relations: Vpullup<Vset and Vpullup<Vreset, as described above, the reset voltage Vreset may be set by using only the relation: Vpullup<Vset.

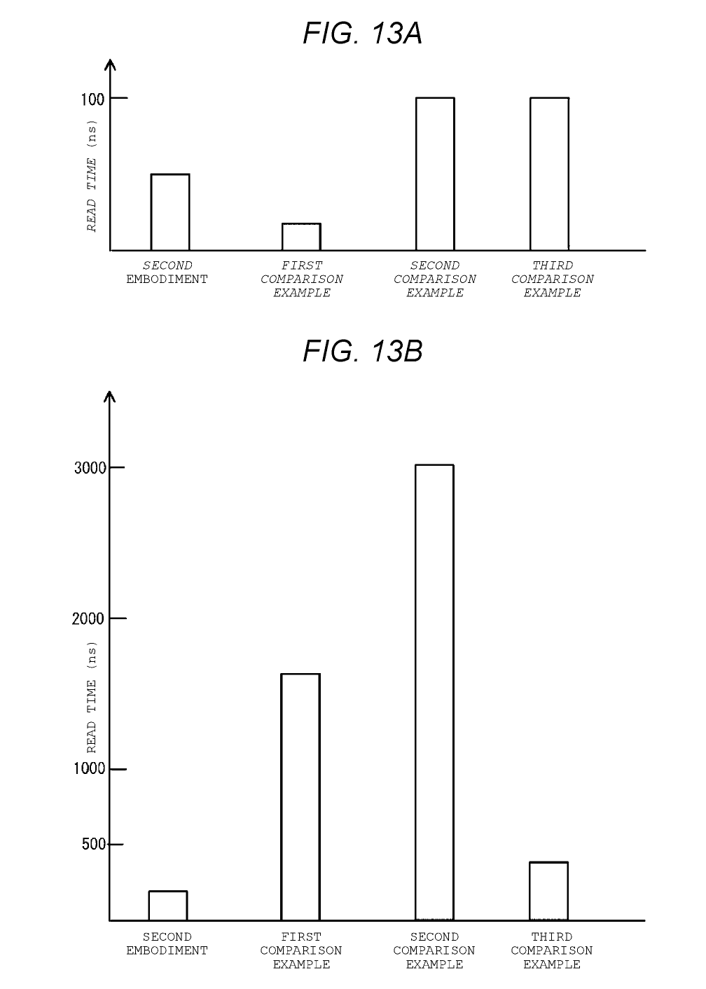

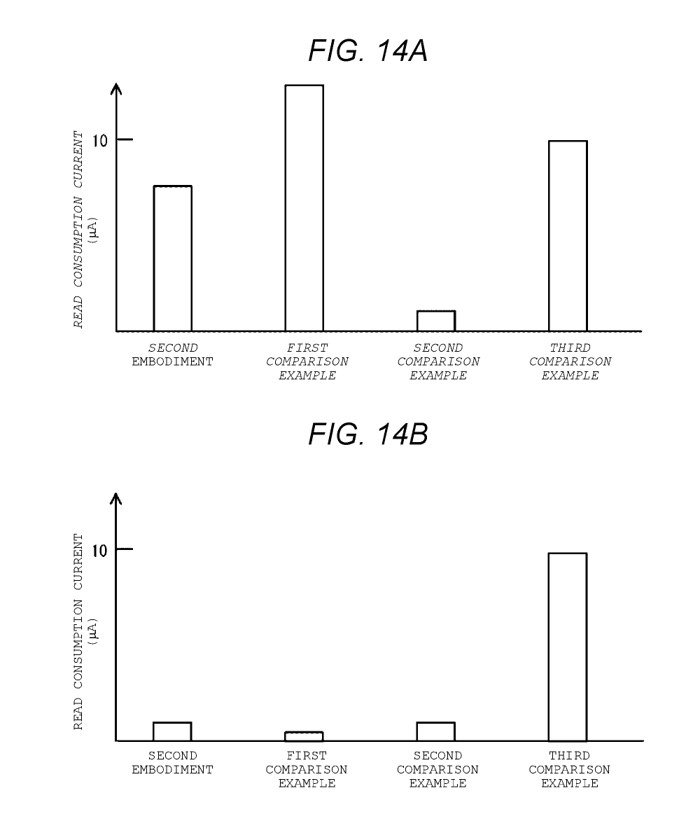

Next, the read time of the memory cell and the read current consumption of the memory cell is described with reference to FIGS. 13A and 13B and FIGS. 14A and 14B. FIGS. 13A and 13B are diagrams illustrating the read time of the memory cell, and FIG. 13A is diagram illustrating the read time in the lowest resistance value cell and FIG. 13B is a diagram illustrating the read time in the highest resistance value cell. FIGS. 14A and 14B are diagrams illustrating the read current consumption, and FIG. 14A is the read current consumption in the lowest resistance value cell and FIG. 14B is a diagram illustrating the read current consumption in the highest resistance value cell.

The read current consumption is the same as that of the first embodiment (refer to FIGS. 14A and 14B) and the read time of the lowest resistance value cell is the same as that of the first embodiment. Therefore, the read time in the highest resistance value cell will be described while comparing the first to third comparison examples.

As illustrated in FIG. 13B, the read time in the highest resistance value cell in the second embodiment (example embodiment) can be shortened to 1/12 as compared to that in the first comparison example, can be shortened to 1/20 as compared to that in the second comparison example, and can be shortened to ½ compared to that in the third comparison example.

Therefore, both the minimization of the read time of the memory cell and reduction of the read current consumption can be achieved.

### Third Embodiment

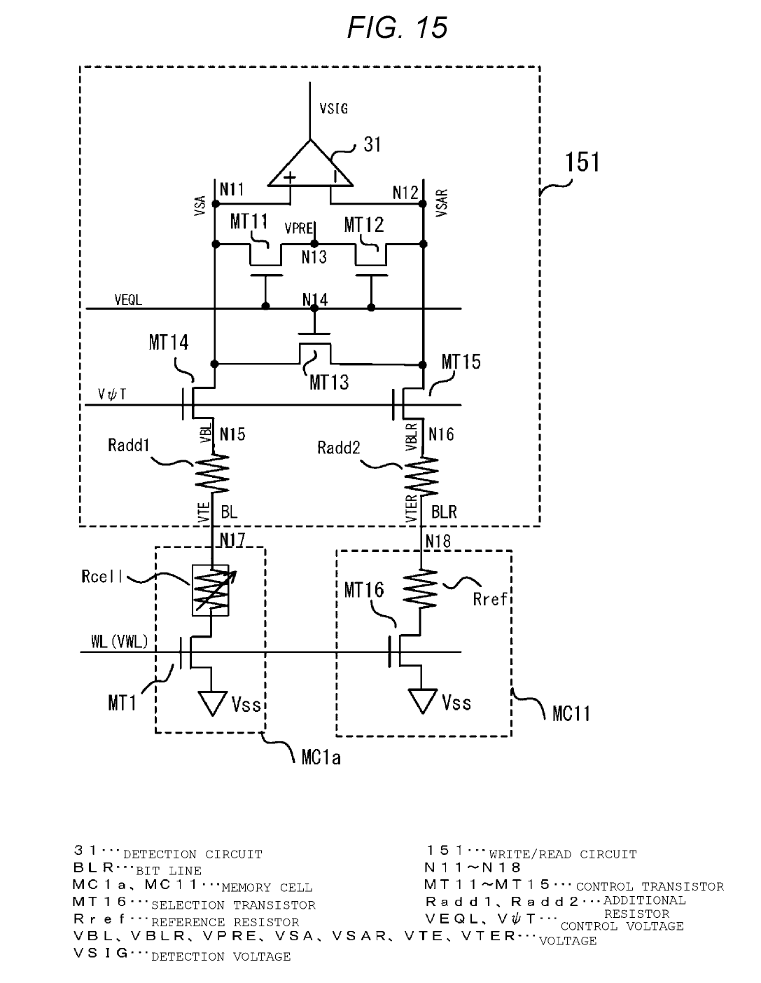

Next, a non-volatile semiconductor memory device of a third embodiment will be described with reference to the drawings. FIG. 15 is a circuit diagram illustrating a write/read circuit.

FIG. 15 is a circuit that employs a charge transfer amplifier. The potential difference on the bit line with a large capacitance is transferred to the sense node with a small capacitance and the sensing (write/read) is performed. As a result, the increase in the sense-margin can be achieved.

In the third embodiment, the detection circuit compares a sense voltage of a first memory cell and a reference sense voltage of a second memory cell, and both the minimization of the read time of the memory cell and reduction of the read current consumption can be achieved.

As illustrated in FIG. 15, a write/read circuit 151 of the non-volatile semiconductor memory device in the third embodiment includes a detection circuit 31, additional resistor Radd1, additional resistor Radd2, control transistors MT11, MT12, MT13, MT14, and MT15. The non-volatile semiconductor memory device in the third embodiment is a PCRAM.

The additional resistor Radd1 is connected to the memory cell MC1a (also referred to as the first memory cell) via the bit line BL (also referred to as the first bit line). The additional resistor Radd2 has a resistance value same as that of the additional resistor Radd1. The additional resistor Radd2 is connected to the memory cell MC11 (also referred to as the second memory cell) via the bit line BLR (also referred to as the second bit line). The memory cell MC11 functions as a reference memory cell.

The memory cell MC1a includes a variable resistance element Rcell and a selection transistor MT1. One end of the variable resistance element Rcell is connected to the bit line BL (at node N17). One end (e.g., drain) of the selection transistor MT1 is connected to the other end of the variable resistance element Rcell, and the other end (e.g., source) thereof is connected to the low potential side power supply Vss, and the control terminal (gate) thereof is connected to the word line WL. When the voltage (VWL) of the word line WL is in a “high” level, the selection transistor MT1 enters an ON state.

The memory cell MC11 includes a reference resistor Rref and a selection transistor MT16. One end of the reference resistor Rref is connected to the bit line BLR (at node N18). One end (drain) of the selection transistor MT16 is connected to the other end of the reference resistor Rref, the other end (source) thereof is connected to the low potential side power supply Vss, and the control terminal (gate) thereof is connected to the word line WL. When the voltage VWL at the word line WL is in a “high” level, the selection transistor MT1 enters an ON state.

One end of the additional resistor Radd1 is connected to the node N15 and the other end thereof is connected to the bit line BL (at node N17). One end of the additional resistor Radd2 is connected to the node N16 and the other end thereof is connected to the bit line BLR (at node N18).

One end (drain) of the control transistor MT14 is connected to the node N11, the other end (source) thereof is connected to the node N15, and a control voltage VψT is applied to the control terminal (gate) thereof. One end (drain) of the control transistor MT15 is connected to the node N12, the other end is connected to the node N16, and the control voltage VψT is applied to the control terminal (gate) thereof. When the control voltage VψT is in a “high” level, the control transistor MT14 and the control transistor MT15 enter ON states.

One end of the control transistor MT13 is connected to the node N11, the other end thereof is connected to the node N12, and a control voltage VEQL is applied to the control terminal (gate) thereof. One end of the control transistor MT11 is connected to the node N11, the other end is connected to the node N13 to which a voltage VPRE is applied, and the control voltage VEQL is applied to the control terminal (gate) thereof. One end of the control transistor MT12 is connected to the node N12, the other end is connected to the node N13 to which a voltage VPRE is applied, and the control voltage VEQL is applied to the control terminal (gate). When the control voltage VEQL is in a “high” level, the control transistors MT11 to MT13 enter ON states.

The non-inverting amplifier terminal (+) on the input side of the detection circuit 31 is connected to the node N11 and the node N12 is connected to the inverting amplifier terminal (−) on the input side thereof. The detection circuit 31 performs the comparison calculation processing on the voltage at the inverting amplifier terminal (−) on the input side thereof and the voltage at the non-inverting amplifier terminal (+) on the input side thereof with the voltage at the inverting amplifier terminal (−) on the input side as a reference.

The detection circuit 31 operates during the reading of the data stored in the memory cell MC1. Specifically, a voltage VSA, which is a sense voltage of the first memory cell, is input to the non-inverting amplifier terminal (+) on the input side of the detection circuit 31 and a voltage VSAR, which is a sense voltage of the reference memory cell, is input to the inverting amplifier terminal (−) on the input side of the detection circuit 31, and the detection circuit 31 performs a comparison and outputs the result of the comparison as a detection voltage VSIG.

In a case where any of multilevel data is stored in the variable resistance element Rcell, the detection voltages VSIG are output a multiple number of times while changing the value of the voltage VPRE applied to the node N13 so as to narrow down the specific value of the stored data in the variable resistance element Rcell.

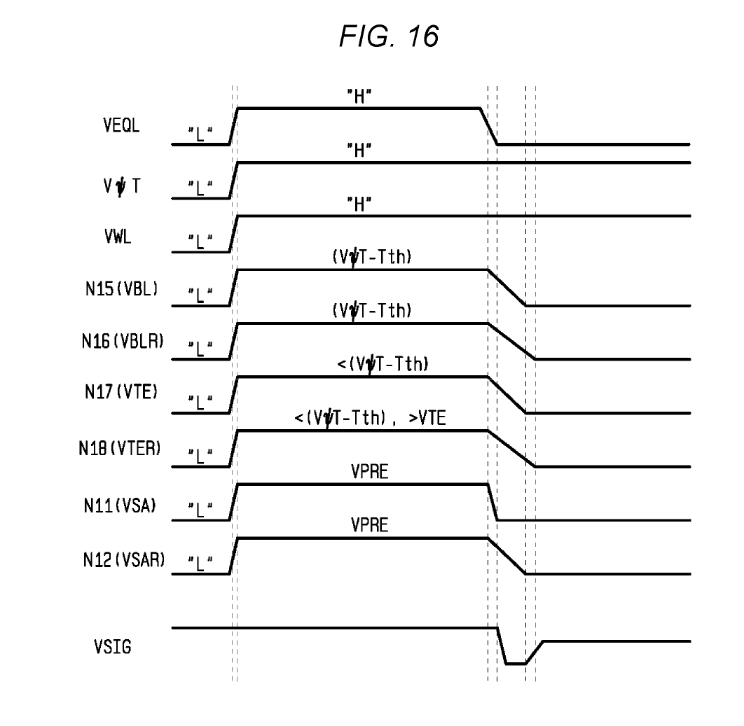

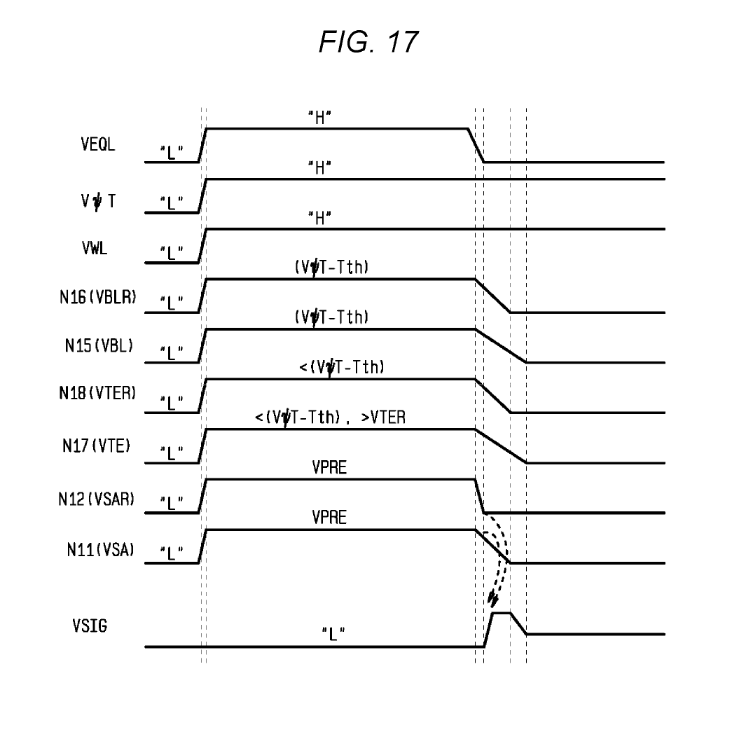

Next, the read operation of the memory cell of the non-volatile semiconductor memory device in an example embodiment will be described with reference to FIG. 16 and FIG. 17. FIG. 16 is a timing chart illustrating the read operation of a memory cell in a low resistance state (“0 data” cell). FIG. 17 is a timing chart illustrating the read operation of a memory cell in a high resistance state (“1 data” cell).

The third embodiment is now explained with reference to FIG. 16. By the charge transfer transistors (MT14 and MT15), a minute signal potential (signal charge: VBL, VBLR, VTE and VTER), which is on the bit line with the large capacitance, is transferred to the sense node (VSA, VSAR) with the small capacitance. After that, the potential difference is detected and amplified by the detection circuit 31. As the result, the sense margin may be increased.

As illustrated in FIG. 16, in the read operation of the memory cell in the low resistance state, at first, when the control voltage VEQL is high and the sense node potentials (VSA, VSAR) are at VPRE, the potentials of VψT and VWL will rise simultaneously therewith. The potential (voltage) VBL of the bit line and the potential (voltage) VBLR of the reference bit line are supplied from the sense node via the transistors, MT14 and MT15. Consequently, the potentials VBL and VBLR will be at VψT−Vth, where Vth is the threshold voltage of the transistors MT14 and MT15.

As shown in FIG. 16, the potentials, VTE and VTER, are each smaller than the potential, VψT−Vth, and VTER>VTE. Further, the potential, VψT−Vth, will become the operating point potential, which is set according to the relation between the memory cell resistance (R cell) and the reference cell resistance (R ref). As explained in the first embodiment and the second embodiment, the operating point potential is set to avoid the phase transition occurring region shown in FIG. 4. After each potential has reached its expected value, the signal VEQL will be lowered to “Low”.

When the transistors MT11, MT12, MT14 are “off”, the potential (voltage) of the bit line will be not supplied from the sense node. As the result, the potential (voltage) of the bit line will be reduced because the potential (voltage) of the bit line has fallen via the cell transistor.

As the reference cell resistance (Rref) is set to be larger than the memory cell resistance (Rcell), the potentials, VBLR and VTER, decrease gradually, compared to the potentials, VBL and VTE. Due to the fall of “VBL, VTE and VBLR, VTER”, the potential between gate and source of the charge transfer transistors, MT14 and MT15, will be larger than the threshold voltage thereof and the charge transfer transistors (MT14 and MT15) will be turned “ON”.

As a result, the potential (voltage) will be transferred from the sense node (VSA, VSAR) to the corresponding bit line, and the potential difference between bit lines will be amplified because the capacitance of the sense node is smaller than the capacitance of the corresponding bit line. Accordingly, the amplification effect between the sense nodes is increased and the sense margin in the detection circuit 31 is increased.

FIG. 16 is a timing chart of various potentials according to which VSIG will be generated by “detection/amplification” of the difference between N11(VSA) and N12(VSAR)”. The output signal VSIG of the detection circuit 31 is set to be “L” before the sense amplification.

At the timing when VEQL is “Low”, VSIG, which is set to be “Low”, will be allowed to increase. When the potential (voltage) of a non-inverted amplification terminal (VSA) is lower than the potential (voltage) of an inverted amplification terminal (VSAR), the detection circuit 31 will output “Low”. At the timing when VSA is almost equal to VSAR, both VSA and VSAR will be at an intermediate potential.

The third embodiment is now explained with reference to FIG. 17. Referring to FIG. 15, by the charge transfer amplifier (MT14, MT15), a minute signal potential (signal charge: VBL, VBLR, VTE and VTER), which is on the bit line with the large capacitance, is transferred to the sense node (VSA, VSAR) with the small capacitance. After that, the potential difference is detected and amplified by the detection circuit 31. As the result, the sense margin may be increased.

As illustrated in FIG. 17, in the read operation of the memory cell in the high resistance state, at first, when the control voltage VEQL is high and the sense node potentials (VSA, VSAR) are at VPRE, the potentials VψT and VWL will rise simultaneously therewith. The potential (voltage) VBL of the bit line and the potential (voltage) VBLR of the reference bit line are supplied from the sense node via the transistors, MT14 and MT15. Consequently, the potentials VBL and VBLR will be at VψT−Vth, where Vth is the threshold voltage of the transistors MT14 and MT15.

As shown in FIG. 17, the potentials, VTE and VTER, are each smaller than the potential, VψT−Vth, and VTER>VTE. Further, the potential, VψT−Vth, will become the operating point potential, which is set according to the relation between the memory cell resistance (R cell) and the reference cell resistance (Rref). As explained in the first embodiment and the second embodiment, the operating point potential is set to avoid the phase transition occurring region in FIG. 4. After each potential has reached its expected value, the signal VEQL will be lowered to “Low”.

When the transistor MT11, MT12, MT14 are “off,” the potential (voltage) of the bit line will be not supplied from the sense node. As the result, the potential (voltage) of the bit line will be reduced because the potential (voltage) of the bit line has fallen via the cell transistor.

As the reference cell resistance (Rref) is set to be smaller than the memory cell resistance (Rcell), the potentials, VBLR and VTER, decrease rapidly, compared to the potentials VBL and VTE. Due to the fall of “VBL, VTE and VBLR, VTER”, the potential between gate and source of the charge transfer transistors, MT14 and MT15, will be larger than the threshold voltage thereof and the charge transfer transistors (MT14 and MT15) will be turned “ON”.

As a result, the potential (voltage) will be transferred from the sense node (VSA, VSAR) to the corresponding bit line, and the potential difference between the bit lines will be amplified because the capacitance of the sense node is smaller than the capacitance of the corresponding bit line. Accordingly, the amplification effect between sense nodes is increased and the sense margin in the detection circuit 31 is increased.

FIG. 17 is a timing chart of various potentials according to which VSIG will be generated by “detection/amplification” between N11(VSA) and N12(VSAR)”. The output signal VSIG of the detection circuit 31 is set to be “L” before the sense amplification.

At the timing when VEQL will be “Low”, VSIG, which is set to be “Low”, will be allowed to increase. When the potential (voltage) of a non-inverted amplification terminal (VSA) is higher than the potential (voltage) of an inverted amplification terminal (VSAR), the detection circuit 31 will output “High”. At the timing when VSA is almost equal to VSAR, both VSA and VSAR will be at an intermediate potential.

As described above, the write/read circuit 151 including the detection circuit 31, the additional resistor Radd1, the additional resistor Radd2, and the control transistors MT11 to MT15 are provided in the variable resistance non-volatile semiconductor memory device of the third embodiment. The additional resistor Radd1 is connected to the memory cell MC1a via the bit line BL. The additional resistor Radd2 has the same resistance value as the additional resistor Radd1. The additional resistor Radd2 is connected to the memory cell MC11 via the bit line BLR. The memory cell MC1a includes the variable resistance element Rcell and the selection transistor MT1. The memory cell MC11 includes the reference resistor Rref and the selection transistor MT16. The voltage VSA at the node N11 which is the sense voltage of the first memory cell is input to the non-inverting amplifier terminal (+) on the input side of the detection circuit 31, and the voltage VSAR at the node N12 which is the sense voltage of the reference memory cell is input to the inverting amplifier terminal (−) on the input side of the detection circuit 31, and the detection circuit 31 performs the comparison processing. In the read operation of the memory cell in the low resistance state, the detection voltage VSIG of low level is output from the detection circuit 31. In the read operation of the memory cell in the high resistance state, the detection voltage VSIG of high level is output from the detection circuit 31.

Therefore, it is possible to reduce the read time of the memory cell and the read current consumption.

The example embodiments described above can also be applied to non-volatile semiconductor memory devices that store data using resistance changes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A variable resistance non-volatile semiconductor memory device, comprising:
a memory cell including variable resistance element connected in series with a switching element having a control terminal connected to a word line, a first end of the memory cell being connected to a bit line, a second end of the memory cell being connected to a first power supply line;
a first resistor connected between a second power supply line and the bit line, wherein
the first power supply line is a low potential and the second power supply line is a high potential, and
during a reading operation of the memory cell, a read current flows through the first resistor and the memory cell.

2. The variable resistance non-volatile semiconductor memory device according to claim 1, further comprising:
a control transistor connected between a pull-up voltage line and a node that is between the first resistor and the memory cell, a control terminal of the control transistor being connected to a control signal line, wherein
when the control transistor is in an ON state the pull-up voltage line is electrically connected to the bit line.

3. The variable resistance non-volatile semiconductor memory device according to claim 2, further comprising:
a controller configured to supply a control signal to the control signal line to place the control transistor in the ON state before the reading operation of the memory cell is started so as to pre-charge the bit line to the pull-up voltage.

4. The variable resistance non-volatile semiconductor memory device according to claim 1, further comprising:
a differential amplifier having a first input terminal connected to a node that is between the first resistor and the memory cell, and second input terminal connected to a reference voltage source.

5. The variable resistance non-volatile semiconductor memory device according to claim 1, further comprising:
a write/read circuit connected to an output terminal of the differential amplifier.

6. The variable resistance non-volatile semiconductor memory device according to claim 1, wherein the variable resistance element is configured to have one of a plurality of resistance states, each of the plurality of resistance states corresponding to a different data value in a multilevel data storage scheme.

7. The variable resistance non-volatile semiconductor memory device according to claim 1, wherein the memory cell is one of a resistive random access memory (ReRAM), a phase-change random access memory (PCRAM), an interfacial phase change memory (iPCM), a conductive-bridging random access memory (CBRAM), an electrically erasable programmable read-only memory (EEPROM), a ferroelectric memory (FeRAM), or a magnetoresistive random access memory (MRAM).

8. The variable resistance non-volatile semiconductor memory device according to claim 1, wherein the memory cell is a phase-change random access memory (PCRAM)-type memory cell.

9. The variable resistance non-volatile semiconductor memory device according to claim 1, wherein the variable resistance element is between the first resistor and the selection transistor.

10. A non-volatile memory device, comprising:
a bit line having a sense node thereon;
a variable resistance element connected to the bit line and having at least two different resistance states;
a first resistor connected between the bit line and a first power supply line, the sense node being between the first resistor and the variable resistance element;
a selection transistor connected in series with the variable resistance element between the variable resistance element and a first power supply line, a control terminal of the selection transistor being connected to a word line; and
a sense amplifier having a first input terminal connected to the sense node.

11. The non-volatile memory device according to claim 10, further comprising:
a control transistor connected between a pull-up voltage line and the sense node, wherein when the control transistor is in an ON state the sense node is electrically connected to the pull-up voltage line.

12. The non-volatile memory device according to claim 11, further comprising:
a controller configured to place the control transistor in the ON state before a reading operation begins so as to pre-charge the bit line to the pull-up voltage.

13. The non-volatile memory device according to claim 10, further comprising:
a write/read circuit connected to an output terminal of the sense amplifier.

14. The non-volatile memory device according to claim 10, wherein the variable resistance element is configured to have any one of a plurality of resistance states, each of the plurality of resistance states corresponding to a different data value in a multilevel data storage scheme.

15. The non-volatile memory device according to claim 10, wherein non-volatile memory device is one of a resistive random access memory (ReRAM), a phase-change random access memory (PCRAM), an interfacial phase change memory (iPCM), a conductive-bridging random access memory (CBRAM), an electrically erasable programmable read-only memory (EEPROM), a ferroelectric memory (FeRAM), or a magnetoresistive random access memory (MRAM).

16. The non-volatile memory device according to claim 10, wherein the variable resistance element is a phase-change random access memory (PCRAM)-type.

17. The non-volatile memory device according to claim 10, wherein the variable resistance element is between the first resistor and the selection transistor.

18. A variable resistance non-volatile semiconductor memory device, comprising:
a first resistor having a first resistance value;
a first memory cell that including a variable resistance element and a first selection element connected in series with the first resistor via a first bit line;
a second resistor having the first resistance value;
a second memory cell that including a reference resistor and a second selection element connected in series with second resistor via a second bit line; and
a detection circuit having a first input terminal connected to first memory cell via the first resistor and a second input terminal connected to second memory cell via the second resistor, the detection circuit being configured to perform a comparison on a sense voltage of the first memory cell and a sense voltage of the reference memory cell during a reading operation and output a result of the comparison as a detection voltage.

19. The variable resistance non-volatile semiconductor memory device according to claim 18, wherein the variable resistance element is configured to have any one of a plurality of resistance states, each of the plurality of resistance states corresponding to a different data value in a multilevel data storage scheme.

20. The non-volatile memory device according to claim 18, wherein the variable resistance element is a phase-change random access memory (PCRAM)-type.
